(19) United States
(12) Patent Application Publication
(10) Pub. No.: US 2009/0104567 A1
(43) Pub. Date: Apr. 23, 2009

(54) APPARATUS FOR FABRICATING SEMICONDUCTOR DEVICE AND METHOD THEREOF

(76) Inventor: Dong-Chan Lee, Siheung-si (KR)

Correspondence Address: SHERR & VAUGHN, PLLC, 620 HERNDON PARKWAY, SUITE 200, HERNDON, VA, 20170, US

(21) Appl. No.: 12/246,664

(22) Filed: Oct. 7, 2008

(30) Foreign Application Priority Data
Oct. 22, 2007 (KR) 10-2007-0105996

(51) Int. Cl. G03F 7/20; G03B 27/54

(52) U.S. Cl. 430/319; 355/67

(57) ABSTRACT

An apparatus for fabricating a semiconductor device and method thereof are disclosed, by which an angle of light diffracted by a reticle can be decreased in a manner of filling up an empty space between a reticle and a frame with a transparent substance of high purity to maximize real resolution on and/or over a semiconductor wafer.

This application claims priority under 35 U.S.C. §119 to Korean Patent Application No. 10-2007-0105996 (filed on Oct. 22, 2007), which is hereby incorporated by reference in its entirety.

### BACKGROUND

An optical microlithography system is used for semiconductor device fabrication. The optical microlithography system may include a light source system, a reticle system having a pattern and a frame, and a semiconductor wafer. While light may travel through an empty space between a reticle and a frame, it is diffracted. Therefore, resolution of a pattern exposed to a photosensitive layer provided on a semiconductor wafer is degraded.

### SUMMARY

Embodiments relate to an apparatus for fabricating a semiconductor device and a method thereof that is particularly suitable for using a reticle and a pellicle.

Embodiments relate to an apparatus for fabricating a semiconductor device and method thereof by which an angle of light diffracted by a reticle can be decreased in a manner of filling up an empty space between the reticle and a frame with a transparent substance of high purity.

Embodiments relate to a method of fabricating a semiconductor device that may include at least one of the following steps: providing a light source system for emitting light; and then providing a reticle having a pattern to load a frame thereon; and then forming a transparent substance in an empty space between the frame and the reticle; and then providing a semiconductor wafer having a photosensitive layer thereon; and then exposing the photosensitive layer according to the pattern by enabling light to pass through the reticle and the transparent substance; and then forming the semiconductor device by processing the semiconductor wafer according to the pattern. In accordance with embodiments, after forming the transparent substance in the empty space between the frame and the reticle, the method may further include forming a protective layer on the frame to be spaced apart from a surface of the reticle in a predetermined distance.

Embodiments relate to a method of fabricating a semiconductor device that may include at least one of the following steps: providing a light source system; and then providing a reticle including a body and a plurality of patterns formed on the body; and then forming a transparent material layer on the body including the patterns; and then providing an exposure system; and then providing a semiconductor wafer having a photosensitive layer formed thereon such that the exposure equipment is positioned in a light-travel path between the transparent material layer and the semiconductor wafer; and then exposing the photosensitive layer according to the pattern by transmitting light through the reticle and the transparent substance using the light source system; and then processing the semiconductor wafer according to the pattern.

Embodiments relate to an apparatus for fabricating a semiconductor device that may include at least one of the following: a light source system for emitting light; a reticle having a pattern; a frame loaded on and/or over the reticle; a transparent substance in an empty space between the frame and the reticle; and a semiconductor wafer having a photosensitive layer provide thereon. In accordance with embodiments, light passes through the reticle, the transparent substance and the protective layer to expose the photosensitive layer according to the pattern. In accordance with embodiments, the semiconductor wafer is processed according to the pattern to fabricate the semiconductor device. The apparatus in accordance with embodiments may further include a protective layer formed on and/or over the frame and spaced apart a predetermined distance from a surface of the reticle. Accordingly, an angle of light diffracted by a reticle can be decreased in a manner of filling up an empty space between a reticle and a frame with acryl that is a transparent substance of high purity.

Embodiments, therefore, can enhance and maximize an inevitable diffraction extent of light from a reticle that is a start point of light traveling, thereby enhancing resolution.

### DRAWINGS

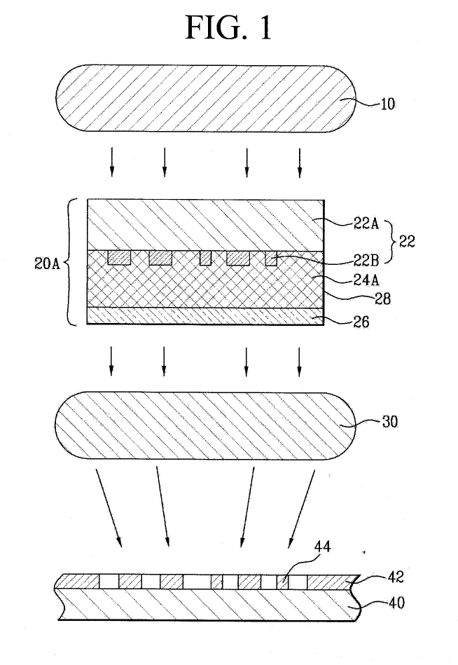

Example FIGS. 1 to 4 illustrate an apparatus for fabricating a semiconductor device and methods of fabricating a semiconductor device in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

As illustrated in example FIG. 1, an apparatus for fabricating a semiconductor device in accordance with embodiments may include light source system 10, reticle system 20A, exposure system 30, photosensitive layer 42 and semiconductor wafer 40. Light source system 10 is a light-emitting source that emits light and can include a fluorine excimer laser. Reticle system 20A includes reticle 22, frame 28 loaded on and/or over a surface of reticle 22, transparent substance 24A and protective layer 26. Reticle 22 has pattern 22B formed on and/or over body 22A and may take the form of a photomask or a mask. Body 22A can be formed of quartz. Pattern 22B can be implemented into a specific shape composed of one of chromium (Cr) and MoSiN.

Transparent substance 24A can be formed on and/or over pattern 22B including body 22A. Transparent substance 24A can be composed of transparent acryl having high purity. Acryl 24A is provided in an empty space between frame 28 and reticle 22. Acryl 24A is a type of plastic and a representative type of acryl is acetone, cyanic acid and methyl alcohol as raw material. Acryl 24A is the polymer of metacrylic acid methylester (metacrylic acid methyl) having specific gravity of 1.18. Acryl 24A in accordance with embodiments may have the following physical properties. Acyl 24A is colorless, transparent, behaves as an electric insulator, water-resistant, chemical resistant, transmits light, and more particularly, ultraviolet light better than normal glass. A refractive index of acryl 24A is 1.49. Acryl 24A cannot change colors even when exposed to the outside atmosphere. Acryl 24A can be injection-molded by compression at a temperature over 150° C. Acyl 24A is formed as a transparent panel 24A by pouring acrylic material into a mold or cast. If the empty space between reticle 22 and frame 28 is filled up with acryl 24A heated into a chemical compound, a corresponding pattern is damaged less than a pattern of other substance owing to low melting point. Acryl 24A can be easily processed and has excellent transparency as organic glass.

Protective layer 26 is formed on and/or over frame 28 and spaced apart a predetermined distance from a surface of reticle 22. Hence, small dust on and/or over protective layer 26 deviates from a focus not to distort a mask pattern on reticle 22. Protective layer 26 plays a role in protecting reticle 22 and may include a pellicle film that is a free-standing film. Protective layer 26 is able to transmit almost every light transmitted from light source system 10. Generally, a distorted pattern, which may cause malfunction of a semiconductor device by such a small contamination source as dust, may be generated due to a very small feature size accompanied by semiconductor processing. To prevent this problem, protective layer 26 is formed on and/or over frame 28.

Exposure system 30 can be further provided in a light-traveling path between protective layer 26 and semiconductor wafer 40. Photosensitive layer 42 (or photosensitive substance) such as photoresist is provided on and/or over semiconductor wafer 40. Light transmitted from light source system 10 passes through reticle 22, acryl 24A, protective layer 26 and exposure system 30 to perform exposure on photosensitive layer 42 according to pattern 22B. A semiconductor device may then fabricated by processing semiconductor wafer 40 according to the exposed pattern 44. Pattern 22B on and/or over reticle 22 can be several times larger than pattern 44 on and/or over semiconductor wafer 40. A plurality of reticles 22 having different patterns can be used in order determined to process a single semiconductor wafer 40.

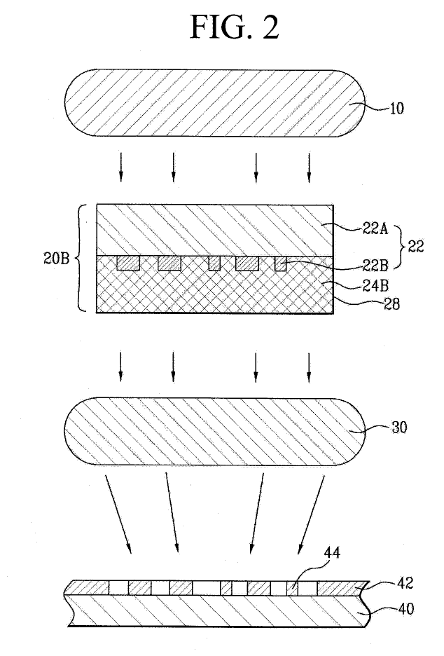

As illustrated in example FIG. 2, a semiconductor device fabricating apparatus is not provided with a protective layer, whereas the former semiconductor device fabricating apparatus illustrated in example FIG. 1 is provided with protective layer 26. This is because acryl 24B can play a role as the protective layer. In particular, acryl 24B serves the same role as pellicle 26 illustrated in example FIG. 1. Reticle system 20B includes reticle 22 and acryl 24B. Hence, light originating from light source system 10 passes through reticle 22 and acryl 24B to expose photosensitive layer 42 according to pattern 22B. Semiconductor wafer 40 is processed according to exposed pattern 44 to fabricate a semiconductor device. Thickness of acryl 24B may be greater than that of former acryl 24A illustrated in example FIG. 1. Except the above-mentioned description, since the semiconductor device fabricating apparatus illustrated in example FIG. 2 is substantially the same as that illustrated in example FIG. 1, details of the respective elements will be omitted in the following description.

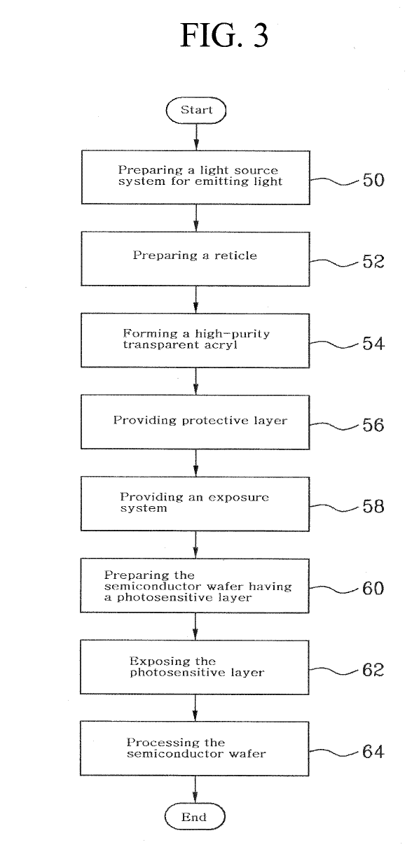

As illustrated in example FIG. 3, initially, a method of fabricating a semiconductor device may include preparing light source system 10 for emitting light [S50]. Reticle 22 including pattern 22B and body 22A are prepared to load frame 28 thereon and/or thereover [S52]. High-purity, transparent acryl 24A is formed in an empty space between frame 28 and reticle 22 [S54]. For instance, in order to form acryl 24A, the empty space between frame 28 and reticle 22 is filled up with high-purity acryl compound. If the acryl compound is heated, such a transparent film as pellicle 26 can be formed as acryl 24A. In this case, the empty space can be filled up with acryl 24A in liquid or solid phase. Thus, if the empty space is filled up with acryl 24A, light is diffracted at an angle smaller than an angle for the diffraction in air. Hence, information of reticle 22, which actually arrives at semiconductor wafer 40, is increased to help the maximization of real resolution.

After completion of step S54, protective layer 26 is provided on and/or over frame 28 to be spaced apart a predetermined distance from a surface of reticle 22 [S56]. Exposure system 30 is provided in a light-traveling path between protective layer 26 and semiconductor wafer 40 [S58]. After completion of step S58, semiconductor wafer 40 having photosensitive layer 42 thereon and/or thereover is prepared [S60]. After completion of step S60, light is transmitted pass through reticle 22, acryl 24A, protective layer 26 and exposure system 30 to expose photosensitive layer 42 according to pattern 22B [S62]. After completion of step S62, a semiconductor device is fabricated by processing semiconductor wafer 40 according to pattern 44 [S64].

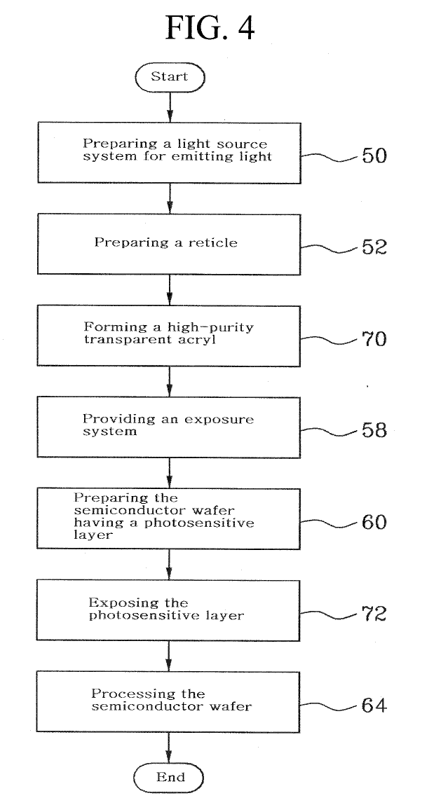

As illustrated in example FIG. 4, initially, a method of fabricating a semiconductor device may include the same steps illustrated in example FIG. 3, but also includes steps 70 and 72. Therefore, details for the same parts are omitted and different parts are explained in the following description. First, acryl 24B is provided in an empty space between frame 28 and reticle 22 [S70]. Thickness of acryl 24B provided in step S70 may differ from that of the acryl formed in step S54. This is because acryl 24B plays an additional role as protective layer 26. After completion of step S70, exposure system 30 is provided in a light-traveling path between protective layer 26 and semiconductor wafer 40 [S58]. After completion of step S60, light is transmitted through reticle 22, acryl 24B and exposure system 30 to expose photosensitive layer 42 according to pattern 22B [S72].

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device comprising:
preparing a light source system for emitting light; and then
preparing a reticle having a pattern; and then
positioning a frame spaced apart over the reticle including the pattern; and then
forming a transparent substance in the space between the frame and the reticle; and then
preparing a semiconductor wafer having a photosensitive layer thereon; and then
exposing the photosensitive layer according to the pattern by transmitting light using the light source system to pass through the reticle and the transparent substance; and then
forming the semiconductor device by processing the semiconductor wafer according to the pattern.

2. The method of claim 1, further comprising, after forming the transparent substance and before preparing the semiconductor wafer, providing a protective layer over the frame and spaced apart a predetermined distance from the reticle.

3. The method of claim 1, wherein the transparent substance comprises an acrylic compound.

4. The method of claim 3, wherein the acrylic compound has a refractive index of 1.49.

5. The method of claim 3, wherein forming the transparent substance comprises:
filling the space with the acrylic compound; and then
heating the acrylic compound.

6. The method of claim 5, wherein filling the space with the acrylic compound comprises injection-molding the acrylic compound by compression at a temperature over 150° C.

7. The method of claim 6, wherein the injection-molding is conducted at a temperature over 150° C.

8. The method of claim 3, wherein forming the transparent substance comprises filling the space with the acrylic compound in a liquid phase.

9. The method of claim 3, wherein forming the transparent substance comprises filling the space with the acrylic compound in a solid phase.

10. The method of claim 1, wherein the protective layer comprises a pellicle film.

11. The method of claim 1, further comprising, after forming the transparent substance and before preparing the semiconductor wafer, providing an exposure system in a light-traveling path between the protective layer and the semiconductor wafer.

12. The method of claim 2, wherein the protective layer comprises a pellicle film.

13. An apparatus for fabricating a semiconductor device, the apparatus comprising:
a light source system for emitting light;
a reticle having a pattern;
a frame provided on the reticle such that an empty space is between the frame and the reticle;
a transparent substance formed in the empty space between the frame and the reticle; and
a semiconductor wafer having a photosensitive layer formed thereon,
wherein the light source emits light through the reticle, the transparent substance and the protective layer to expose the photosensitive layer according to the pattern, and wherein the semiconductor wafer is processed according to the pattern to fabricate the semiconductor device.

14. The apparatus of claim 13, further comprising a protective layer formed on the frame spaced apart a predetermined distance from the reticle.

15. The apparatus of claim 14, wherein the protective layer comprises a pellicle film.

16. The apparatus of claim 13, further comprising an exposure system provided in a light-traveling path between the protective layer and the semiconductor wafer.

17. The apparatus of claim 13, wherein the transparent substance comprises an acrylic compound.

18. The apparatus of claim 17, wherein the acrylic compound has a refractive index of 1.49.

19. A method of fabricating a semiconductor device comprising:
providing a light source system; and then
providing a reticle including a body and a plurality of patterns formed on the body; and then
forming a transparent material layer on the body including the patterns; and then
providing an exposure system; and then
providing a semiconductor wafer having a photosensitive layer formed thereon, wherein the exposure equipment is positioned in a light-travel path between the transparent material layer and the semiconductor wafer,
exposing the photosensitive layer according to the pattern by transmitting light through the reticle and the transparent substance using the light source system; and then
processing the semiconductor wafer according to the pattern.

20. The method of claim 19, wherein forming the transparent substance comprises:
filling the space with an acrylic compound; and then
heating the acrylic compound.
